(19) United States
(12) Patent Application Publication
(10) Pub. No.: US 2025/0015170 A1
(43) Pub. Date: Jan. 9, 2025

(54) SEMICONDUCTOR DEVICE

(71) Applicant: FUJI ELECTRIC CO., LTD., Kanagawa (JP)

(72) Inventor: Yuta SHINODA, Kunitachi-city (JP)

(21) Appl. No.: 18/675,145

(22) Filed: May 28, 2024

(30) Foreign Application Priority Data
Jul. 7, 2023 (JP) 2023-112070

(51) Int. Cl. H01L 29/739; H01L 29/06; H01L 29/10; H01L 29/49

(52) U.S. Cl. CPC H01L 29/7397; H01L 29/0611; H01L 29/1095; H01L 29/495

(57) ABSTRACT

Provided is a semiconductor device comprising a diode portion, comprising: a plurality of trench portions provided at a front surface of a semiconductor substrate; a drift region of a first conductivity type provided on the semiconductor substrate; an anode region of a second conductivity type provided above the drift region in the diode portion; a first plug region of the second conductivity type provided above the drift region in the diode portion, which has a doping concentration higher than a doping concentration of the anode region; a front surface side electrode provided above the semiconductor substrate; and an interlayer dielectric film provided above a mesa portion provided between the plurality of trench portions; wherein the anode region is connected to the front surface side electrode on side surfaces of the plurality of trench portions.

The contents of the following patent application(s) are incorporated herein by reference:
NO. 2023-112070 filed in JP on Jul. 7, 2023

### BACKGROUND

### 1. Technical Field

The present invention relates to a semiconductor device.

### 2. Related Art

A semiconductor device having a configuration that “a barrier metal 5 is in ohmic contact with a diode trench electrode 21a and a p type contact layer 24, and electrically connected to a diode trench electrode and a p type contact layer 24” is described in Patent document 1.

### PRIOR ART DOCUMENT

### Patent Document

Patent Document 1: Japanese Patent Application Publication No. 2022-056498
Patent Document 2: Japanese Patent Application Publication No. 2022-059487

### BRIEF DESCRIPTION OF THE DRAWINGS

FIG. 1 shows an example of the upper surface of the semiconductor device 100 in the present example.

FIG. 2A shows an example of the upper surface of the semiconductor device 100 in the present example.

FIG. 2B shows an example of the a-a′ cross-section of the semiconductor device 100 in the present example.

FIG. 2C shows an example of the b-b′ cross-section of the semiconductor device 100 in the present example.

FIG. 2D shows an example of the c-c′ cross-section of the semiconductor device 100 in the present example.

FIG. 2E shows an example of the d-d′ cross-section of the semiconductor device 100 in the present example.

FIG. 2F shows an example of the e-e′ cross-section of the semiconductor device 100 in the present example.

FIG. 3 shows an example of an enlarged drawing of the upper surface of the semiconductor device 100 in the present example.

FIG. 4 shows a modification example of the enlarged drawing of the upper surface of the semiconductor device 100 in the present example.

FIG. 5 shows an example of the upper surface of the semiconductor device 500 of a comparative example.

FIG. 6A shows a modification example of the upper surface of the semiconductor device 100 in the present example.

FIG. 6B shows an example of the f-f′ cross-section of the semiconductor device 100 in the present example.

FIG. 6C shows an example of the g-g′ cross-section of the semiconductor device 100 in the present example.

FIG. 6D shows an example of the h-h′ cross-section of the semiconductor device 100 in the present example.

FIG. 7A shows a modification example of the semiconductor device 100 in a top view in the present example.

FIG. 7B shows a modification example of the semiconductor device 100 in a top view in the present example.

FIG. 8 shows the relationship between the forward-direction voltage Vf and the reverse recovery loss Err of the semiconductor device 100 in the present example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer or other member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing a positive or negative sign, it means that the direction is parallel to the +Z axis and the −Z axis.

In the present specification, a surface parallel to the upper surface of the semiconductor substrate is referred to as the XY surface, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. Additionally, as used in the present specification, the view of the semiconductor substrate in the Z axis direction is referred to as a planar view. In addition, in the present specification, a direction parallel to the upper surface and the lower surface of the semiconductor substrate may be referred to as a horizontal direction, including an X axis direction and a Y axis direction.

Each embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each embodiment respectively have opposite polarities.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of an N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state.

In the present specification, a description of a P+ type or an N+ type means a doping concentration higher than that of the P type or the N type, and a description of a P− type or an N− type means a lower doping concentration than that of the P type or the N type. In addition, in the present specification, a description of a P++ type or an N++ type means a doping concentration higher than that of the P+ type or the N+ type.

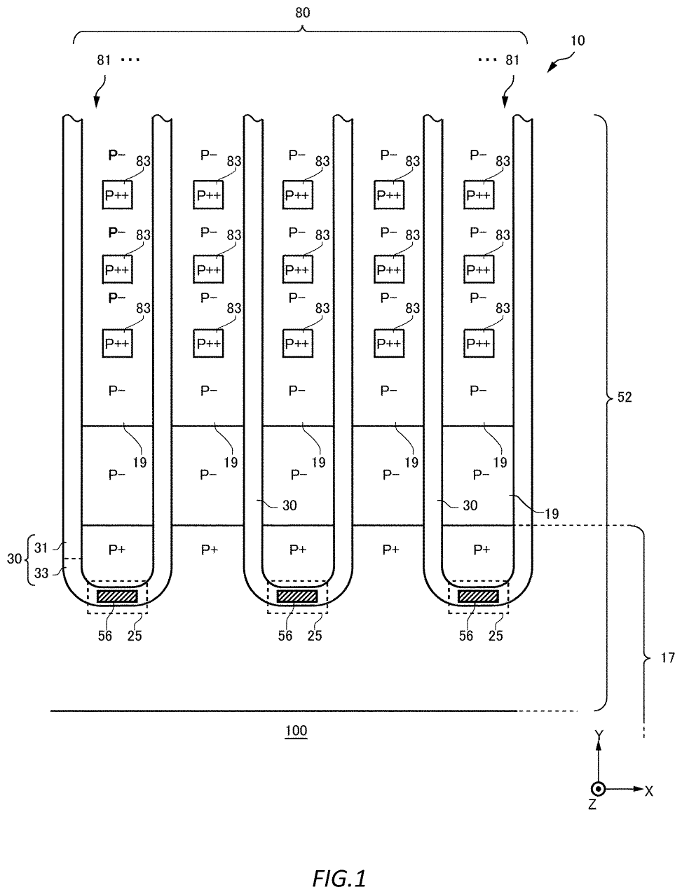

FIG. 1 shows an example of an upper surface of a semiconductor device 100 in the present example. The semiconductor device 100 may include a diode portion 80 having an anode region 19 and a first plug region 83 on a front surface 21 of the semiconductor substrate 10 described below. The semiconductor device 100 includes an interlayer dielectric film 38, a first contact portion 154, and a second contact portion 254 above the front surface 21 of the semiconductor substrate 10, but they are omitted in FIG. 1. The interlayer dielectric film 38, the first contact portion 154, and the second contact portion 254 are described below. In addition, the semiconductor device 100 in the present example includes a front surface side electrode 52 provided above the front surface 21 of the semiconductor substrate 10.

The front surface 21 of the semiconductor substrate 10 is provided with a plurality of trench portions extending in a predetermined direction (the Y axis direction in the present example) and being arrayed in a predetermined direction (the X axis direction in the present example). The plurality of trench portions have a dummy trench portion 30 to which a floating potential or an anode potential is applied. The diode portion 80 in the present example has a dummy trench portion 30. When the semiconductor device 100 is provided with a transistor portion, the diode portion 80 may have a gate trench portion to which a gate potential is applied.

The diode portion 80 is a region where a cathode region 82 provided on a back surface of the semiconductor substrate 10 is projected onto the upper surface of the semiconductor substrate 10. The cathode region 82 has the first conductivity type. The cathode region 82 in the present example is of the N+ type as an example. Details of the cathode region 82 will be described below.

In FIG. 1, the region around the chip end portion that is on the edge (the end portion) side of the semiconductor device 100 is shown, and the other regions are omitted. For example, an edge termination structure portion may be provided in a region in a negative side of the Y axis direction in the semiconductor device 100 in the present example. The edge termination structure portion reduces an electric field strength on the upper surface side of the semiconductor substrate 10. The edge termination structure portion has, for example, a guard ring, a field plate, a RESURF, and a structure combining these. Note that although the present example describes the edge on the negative side in the Y axis direction for convenience, the same applies to other edges of the semiconductor device 100. The edge termination structure portion may be provided to surround the active region on which a main current flows upon the operation of the semiconductor device 100.

The semiconductor substrate 10 may be a silicon substrate, may be a silicon carbide substrate, or may be a nitride semiconductor substrate such as gallium nitride, or the like. The semiconductor substrate 10 in the present example is the silicon substrate.

The front surface side electrode 52 is provided above the dummy trench portion 30, the well region 17, and the anode region 19. The front surface side electrode 52 is formed of a material including metal. At least a partial region of the front surface side electrode 52 may be formed of metal such as aluminum (Al), or an alloy including aluminum, for example, metal alloy such as aluminum-silicon alloy (Al—Si), aluminum-silicon-copper alloy (Al—Si—Cu).

On a lower layer of the region formed of aluminum, the alloy including aluminum or the like, the front surface side electrode 52 may have a barrier metal layer 61 formed of titanium, a titanium compound, or the like. That is, the front surface side electrode may have the barrier metal layer 61 provided inside the first contact portion 154 and the second contact portion 254 described below. The barrier metal layer 61 will be described below.

The front surface side electrode 52 is provided above the semiconductor substrate 10 to sandwich the interlayer dielectric film 38. The interlayer dielectric film 38 is omitted from FIG. 1. A contact hole 56 is provided to pass through the interlayer dielectric film 38.

The contact hole 56 connects the front surface side electrode 52 to a dummy conductive portion in the dummy trench portion 30. In the contact hole 56, a plug layer 62 formed of tungsten or the like may be formed via the barrier metal layer 61. That is, the front surface side electrode 52 may have a plug layer 62 composed of tungsten. The plug layer 62 will be described below.

A connecting portion 25 electrically connects the front surface side electrode 52 and the semiconductor substrate 10. In an example, the connecting portion 25 is provided between the front surface side electrode 52 and the dummy conductive portion. The connecting portion 25 is formed of a conductive material such as polysilicon doped with an impurity. The connecting portion 25 in the present example is polysilicon doped with an N type impurity (N+). The connecting portion 25 is provided above the front surface 21 of the semiconductor substrate 10 via a dielectric film such as an oxide film, or the like.

The dummy trench portion 30 is a trench portion that is electrically connected to the front surface side electrode 52. The dummy trench portion 30 is arrayed at a predetermined interval along a predetermined array direction (the X axis direction in the present example). The dummy trench portions 30 in the present example may have: two extending portions 31 extending along an extending direction (the Y axis direction in the present example) parallel to the front surface 21 of the semiconductor substrate 10 and perpendicular to the array direction; and a connecting portion 33 which connects the two extending portions 31.

At least a part of the connecting portion 33 may be formed to have a curved shape. By connecting end portions of the two extending portion 31 of the dummy trench portion 30, the electric field strength at the end portions of the extending portions 31 can be reduced. At the connecting portion 33 of the dummy trench portion 30, the front surface side electrode 52 may be connected to the dummy conductive portion.

The mesa portion 81 is provided in a region sandwiched between the dummy trench portions 30 adjacent to each other in the diode portion 80. The mesa portion may be a portion of the semiconductor substrate 10 sandwiched between two adjacent trench portions, and may be a portion from the front surface 21 of the semiconductor substrate 10 to a depth of the lowermost bottom portion of each trench portion. An extending portion of each trench portion may be defined as one trench portion. That is, the region sandwiched between two extending portions may be defined as a mesa portion.

The mesa portion 81 has an anode region 19 on the front surface 21 of the semiconductor substrate 10. The mesa portion 81 in the present example has the anode region 19 and the well region 17 on the negative side of the Y axis direction.

The well region 17 is a region of a second conductivity type which is provided on a surface on the front surface 21 side of the semiconductor substrate 10. The well region 17 is an example of a well region provided on the edge side of the semiconductor device 100. The well region 17 is of the P+ type as an example.

The well region 17 is formed in a predetermined range from the end portion of the active region on a side where the front surface side electrode 52 is provided. The well region 17 may be provided in a predetermined range from the active region at a side closer to the edge termination structure portion to the edge termination structure portion. A diffusion depth of the well region 17 may be deeper than the depth of the dummy trench portion 30. A partial region of the dummy trench portion 30 is formed on the well region 17. The bottom ends of the dummy trench portions 30 in the extending direction may be covered by the well region 17.

The anode region 19 is a region of the second conductivity type which is provided above the drift region 18. The drift region 18 will be described below. The anode region 19 in the present example is of P− type, as an example. The doping concentration of the anode region 19 may be 4E16 cm⁻³ or more, or may be 1E17 cm⁻³ or less. It should be noted that the E means the power of 10, and for example, 1E18 cm⁻³ means 1×10¹⁸ cm⁻³.

The anode region 19 in the present example is provided on the front surface 21 of the mesa portion 81. The anode region 19 may be provided in the X axis direction from one dummy trench portion 30 to another dummy trench portion 30 of two dummy trench portions 30 which interpose the mesa portion 81 therebetween. That is, the anode region 19 may be provided to be extended from one trench sidewall of a plurality of trench portions to another trench sidewall in a trench array direction of the plurality of trench portions. The anode region 19 is electrically connected to the front surface side electrode 52 on side surfaces of the plurality of trench portions.

The first plug region 83 is a region of the second conductivity type having a doping concentration higher than that of the anode region 19. The first plug region 83 in the present example is a P++ type, as an example. The doping concentration of the first plug region 83 may be 2E19 cm⁻³ or more, or 2E20 cm⁻³ or less.

The first plug region 83 in the present example is provided to be spaced apart from the trench sidewall of the plurality of trench portions in the trench array direction of the plurality of trench portions. On the front surface 21 of the semiconductor substrate 10, the anode region 19 may be provided between the first plug region 83 and the trench sidewall. In this way, the amount of a dopant implanted into the first plug region 83 is reduced, and the forward-direction voltage Vf of the diode portion 80 can be improved.

In the mesa portion 81, the first plug region 83 and the anode region 19 may be alternately provided in a trench extending direction of the plurality of trench portions. In the mesa portion 81, an area of the anode region 19 on the front surface 21 of the semiconductor substrate 10 may be greater than an area of the first plug region 83 on the front surface 21 of the semiconductor substrate 10. By adjusting the amount of a dopant of the second conductivity type in the diode portion 80, values of the forward-direction voltage Vf and the reverse recovery loss Err of the diode portion 80 can be adjusted.

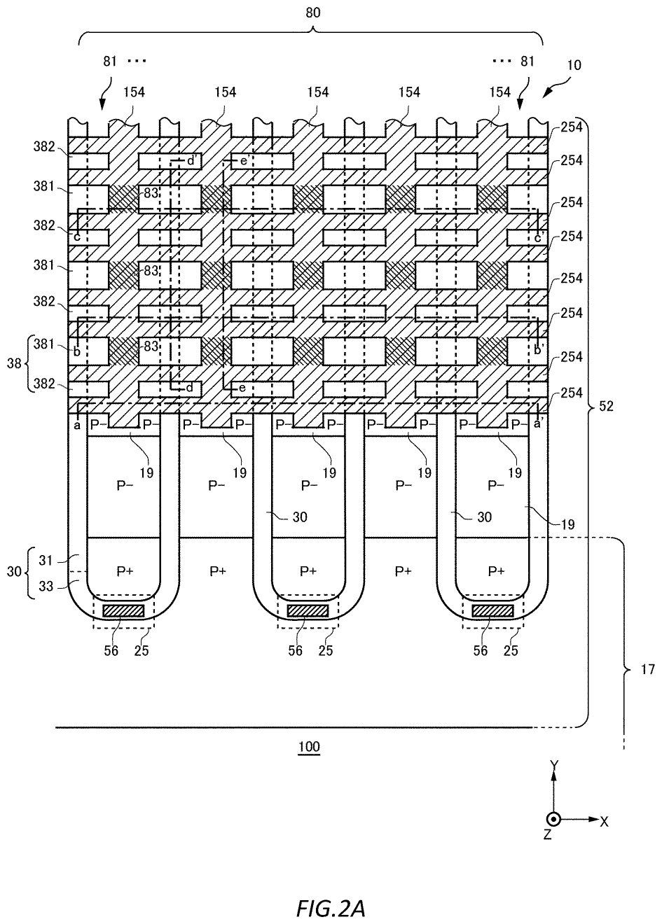

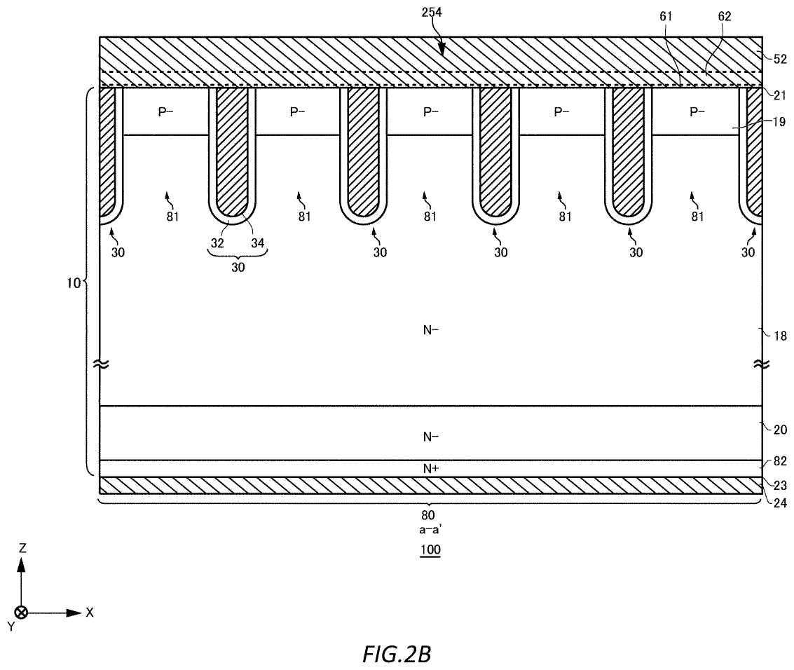

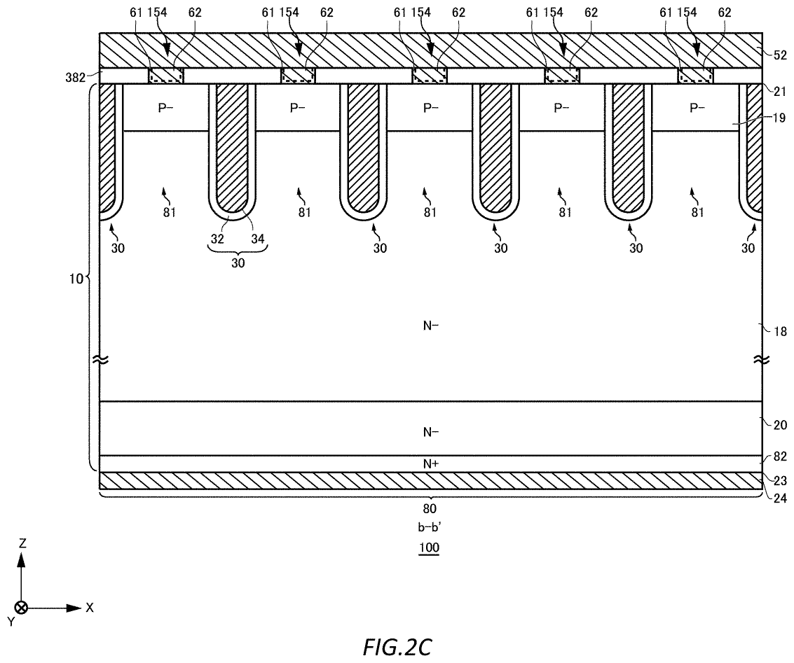

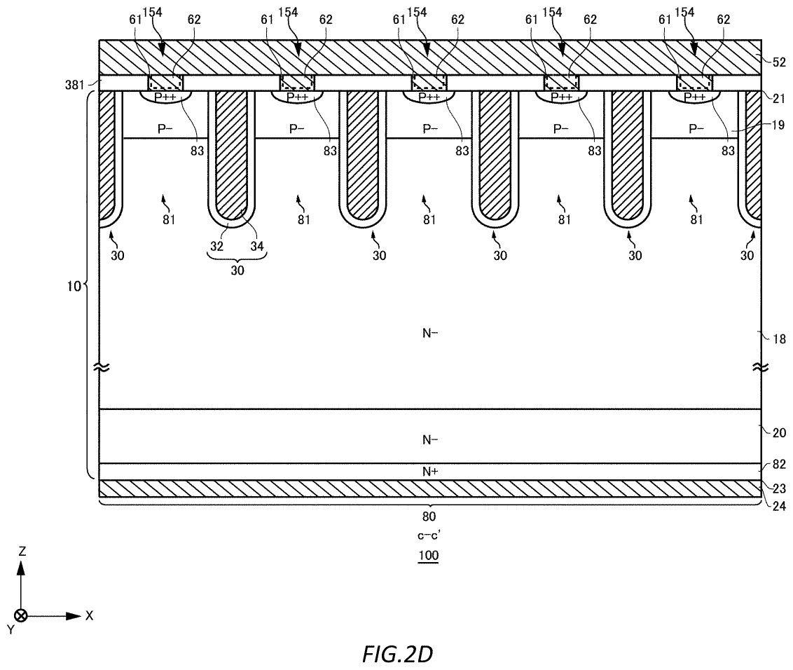

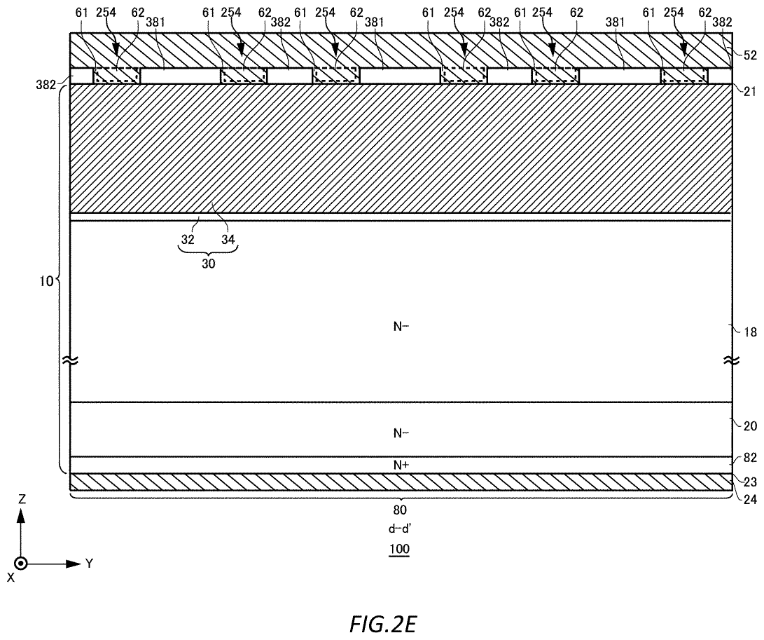

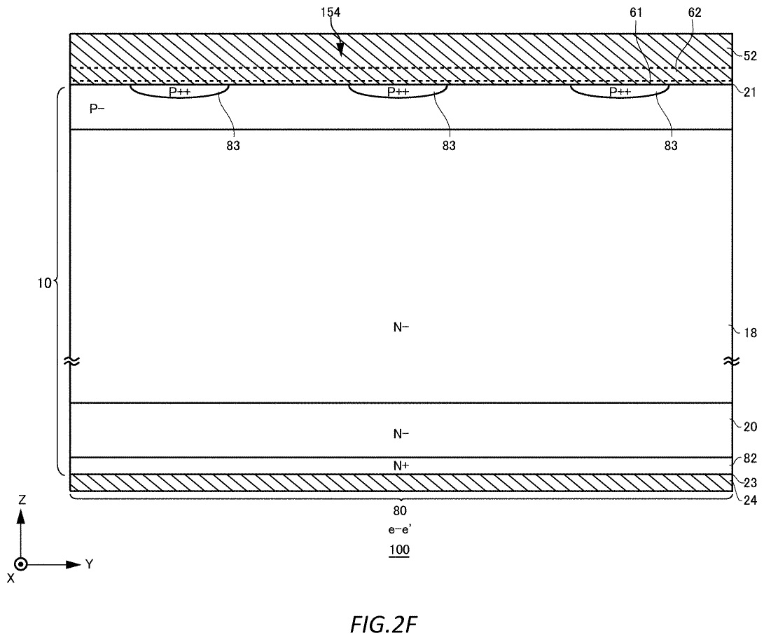

FIG. 2A shows an example of the upper surface of the semiconductor device 100 in the present example. In FIG. 2A, the interlayer dielectric film 38, the first contact portion 154 and the second contact portion 254 omitted in FIG. 1 are shown.

The first contact portion 154 and the second contact portion 254 are provided inside a contact hole which is provided to be extended in a depth direction of the semiconductor substrate 10 from the upper surface of the interlayer dielectric film 38. The first contact portion 154 and the second contact portion 254 are provided to be extended in directions that are different from each other. The first contact portion 154 and the second contact portion 254 may be provided to intersect with each other. The first contact portion 154 and the second contact portion 254 may be integrally formed.

The first contact portion 154 and the second contact portion 254 are examples of the front surface side electrode 52. The first contact portion 154 and the second contact portion 254 include the barrier metal layer 61 and the plug layer 62 inside the interlayer dielectric film 38.

The first contact portion 154 may be provided to be extended in the trench extending direction of the plurality of trench portions above the mesa portion 81. The first contact portion 154 may be connected to the anode region 19, may be connected to the first plug region 83, or may be connected to both the anode region 19 and the first plug region 83.

In the semiconductor device 100, a plurality of first contact portions 154 may be provided. The first contact portions 154 in the present example are arranged in the striped shapes along the dummy trench portion 30. By implanting the dopant via a contact hole for providing the first contact portion 154 and forming the first plug region 83, the amount of the dopant of the second conductivity type in the diode portion 80 is adjusted, and the values of the forward-direction voltage Vf and the reverse recovery loss Err of the diode portion 80 can be adjusted.

The second contact portion 254 may be provided, on the front surface 21 of the semiconductor substrate 10, to be extended in the trench array direction of the plurality of trench portions from one trench sidewall to another trench sidewall, and connected to the mesa portion 81. The second contact portion 254 may be extended, in the trench array direction of the plurality of trench portions, beyond at least one trench portion of the plurality of trench portions, and connected to the at least one trench portion. The second contact portion 254 in the present example is provided to be extended in the trench array direction of the plurality of trench portions, and connected to the plurality of trench portions and the mesa portion 81.

The second contact portion 254 may be provided above the anode region 19 and the plurality of trench portions alternately provided in the trench array direction. The second contact portion 254 may be provided in common in a plurality of mesa portions 81 or may be provided in a single mesa portion 81 in the trench array direction of the plurality of trench portions.

By providing the second contact portion 254, an area of a connecting portion between the front surface side electrode 52 and the semiconductor substrate 10 on the anode region 19 can be greater than that of the case in which the second contact portion 254 is not provided. In this way, by extracting, via the second contact portion 254, a hole which is injected from the first plug region 83, the forward-direction voltage Vf of the diode portion can be improved.

In the semiconductor device 100, a plurality of second contact portions 254 may be provided. The plurality of second contact portion 254 may be provided above the anode region 19 and the plurality of trench portions alternately provided in the trench array direction. The second contact portions 254 in the present example are arranged in the striped shapes along an orientation orthogonal to the dummy trench portion 30. By providing the second contact portion 254, peeling of the plug layer 62 formed of tungsten and the like can be prevented.

The interlayer dielectric film 38 is provided above the mesa portion 81 provided between the plurality of trench portions. The interlayer dielectric film 38 may be provided above the plurality of trench portions.

The interlayer dielectric film 38 may be a silicon oxide film. The interlayer dielectric film 38 may be a BPSG (Boro-phospho Silicate Glass) film, may be a BSG (borosilicate glass) film, or may be a PSG (Phosphosilicate glass) film. The interlayer dielectric film 38 may also include a high temperature silicon oxide (HTO: High Temperature Oxide) film.

The interlayer dielectric film 38 in the present example includes a first interlayer dielectric portion 381 and a second interlayer dielectric portion 382. The first interlayer dielectric portion 381 and the second interlayer dielectric portion 382 may be formed of the same material, or may be formed of different materials.

The first interlayer dielectric portion 381 is provided between the first plug region 83 and the plurality of trench portions in the trench array direction, in a top view. By providing the first interlayer dielectric portion 381, the amount of a dopant that is implanted when the first plug region 83 is formed can be adjusted.

The first interlayer dielectric portion 381 is provided, in the trench array direction, to be sandwiched between a plurality of first contact portions 154 being extended in the trench extending direction. The first interlayer dielectric portion 381 is provided, in the trench extending direction, to be sandwiched between the plurality of second contact portions 254 extending in the trench array direction. That is, the first interlayer dielectric portion 381 is provided to have an island-like shape above the upper surface of the semiconductor substrate 10. In this way, an area of the plug layer 62 of the front surface side electrode 52 is reduced, suppressing the film peeling of the plug layer 62.

The second interlayer dielectric portion 382 is provided between the anode region 19 and the plurality of trench portions in the trench array direction, in a top view. By providing the second interlayer dielectric portion 382, an area of a portion in which the second contact portion 254 and the anode region 19 are connected can be adjusted, and the characteristic of the semiconductor device 100 can be adjusted.

The second interlayer dielectric portion 382 is provided, in the trench array direction, to be sandwiched between a plurality of first contact portions 154 being extended in the trench extending direction. The second interlayer dielectric portion 382 is provided, in the trench extending direction, to be sandwiched between the plurality of second contact portions 254 extending in the trench array direction. That is, the second interlayer dielectric portion 382 is provided to have an island-like shape above the upper surface of the semiconductor substrate 10. In this way, an area of the plug layer 62 of the front surface side electrode 52 is reduced, suppressing the film peeling of the plug layer 62.

FIG. 2B shows an example of the a-a′ cross-section in FIG. 2A. The a-a′ cross-section is an X-Z cross-section passing through the second contact portion 254. The semiconductor device 100 in the present example has, in the a-a′ cross-section, the drift region 18, the anode region 19, the semiconductor substrate 10 in which the cathode region 82 and a buffer region 20 are provided, the front surface side electrode 52, and a back-surface-side electrode 24.

The drift region 18 is a region of the first conductivity type which is provided in the semiconductor substrate 10. The drift region 18 in the present example is of the N− type as an example. The drift region 18 may be a region which has remained without other doping regions formed in the semiconductor substrate 10. That is, a doping concentration in the drift region 18 may be a doping concentration in the semiconductor substrate 10.

The buffer region 20 of a first conductivity type may be provided below the drift region 18. The buffer region 20 in the present example is an N type. A doping concentration in the buffer region 20 is higher than a doping concentration in the drift region 18. The buffer region 20 may function as a field stop layer which prevents a depletion layer expanding from the lower surface side of the anode region 19 from reaching the cathode region 82.

The back-surface-side electrode 24 is formed on a back surface 23 of the semiconductor substrate 10. The back-surface-side electrode 24 is formed of a conductive material such as metal. The material of the back-surface-side electrode 24 may be the same as the material of the front surface side electrode 52, or may be different from the material of the front surface side electrode 52. In addition, the back-surface-side electrode 24 may be obtained by stacking a plurality of metal layers formed of different materials. The back-surface-side electrode 24 is a cathode electrode, as an example.

One or more dummy trench portions 30 are provided on the front surface 21. Each trench portion is provided from the front surface 21 to the drift region 18. In a region on which the anode region 19 is provided, each trench portion passes through the anode region 19 to reach the drift region 18. The configuration of the trench portion passing through the doping region is not limited to the one manufactured in the order of forming the doping region and then forming the trench portion. The configuration of the trench portion passing through the doping region also includes a configuration of the doping region being formed between the trench portions after forming the trench portions.

The dummy trench portion 30 has a dummy trench, a dummy dielectric film 32 and a dummy conductive portion 34 which are formed on the front surface 21 side. The dummy dielectric film 32 is formed covering the inner walls of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10.

The cathode region 82 is provided on the back surface 23 of the semiconductor substrate 10 in the diode portion 80. The cathode region 82 is a region of the first conductivity type which has a doping concentration higher than that of the drift region 18. The doping concentration of the cathode region may be 5E19 cm⁻³ or more, or may be 2E20 cm⁻³ or less.

In the cross-section shown in FIG. 2B, the interlayer dielectric film 38 is not provided on the front surface 21. In this way, compared to a case where the interlayer dielectric film 38 is provided, a hole can be easily extracted from the anode region 19, to improve the forward-direction voltage Vf of the diode portion. A barrier metal layer 61 formed of titanium, titanium compound or the like may be included between the front surface 21 and the front surface side electrode 52. In addition, a plug layer 62 formed of tungsten and the like may be provided on the upper surface of the barrier metal layer 61.

FIG. 2C shows an example of the b-b′ cross-section in FIG. 2A. The b-b′ cross-section is an X-Z cross-section passing through the second interlayer dielectric portion 382 and does not pass through the first plug region 83. The difference from FIG. 2B will be described by using FIG. 2C.

The front surface side electrode 52 has the first contact portion 154. The first contact portion 154 is provided to be sandwiched between the second interlayer dielectric portions 382 in the trench array direction of the plurality of trench portions. That is, the first contact portion 154 is provided to be embedded inside a contact hole provided on the interlayer dielectric film 38.

The barrier metal layer 61 formed of titanium, titanium compound or the like may be included inside the first contact portion 154. The plug layer 62 formed of tungsten and the like may be formed inside the barrier metal layer 61. The semiconductor substrate 10 is connected to the front surface side electrode 52 via the first contact portion 154. Note that the barrier metal layer 61 may be provided on the upper surface of the second interlayer dielectric portion 382.

In FIG. 2C, the second interlayer dielectric portion 382 is provided on the front surface 21 of the semiconductor substrate 10. The second interlayer dielectric portion 382 may be provided to be sandwiched between two first contact portions 154 in the trench array direction of the plurality of trench portions. In addition, the dummy trench portion 30 is covered by the second interlayer dielectric portion 382 in the front surface 21.

FIG. 2D shows an example of the c-c′ cross-section in FIG. 2A. The c-c′ cross-section is an X-Z cross-section passing through the first interlayer dielectric portion 381 and the first plug region 83. The difference from FIG. 2B and FIG. 2C will be described by using FIG. 2D.

The first contact portion 154 is provided to be sandwiched between the first interlayer dielectric portion 381 in the trench array direction of the plurality of trench portions. That is, the first contact portion 154 is provided to be embedded inside a contact hole provided on the interlayer dielectric film 38.

The barrier metal layer 61 formed of titanium, titanium compound or the like may be included inside the first contact portion 154. The plug layer 62 formed of tungsten and the like may be formed inside the barrier metal layer 61. The semiconductor substrate 10 is connected to the front surface side electrode 52 via the first contact portion 154. Note that the barrier metal layer 61 may be provided on the upper surface of the first interlayer dielectric portion 381. The first plug region 83 is provided below the first contact portion 154. The first plug region 83 may be formed by implanting a dopant via the contact hole for providing the first contact portion 154. By providing the first plug region 83, the ohmic contact between the semiconductor substrate 10 and the front surface side electrode 52 can be achieved.

In FIG. 2D, the first interlayer dielectric portion 381 is provided on the front surface 21 of the semiconductor substrate 10. The first interlayer dielectric portion 381 may be provided to be sandwiched between two first contact portions 154 in the trench array direction of the plurality of trench portions. In addition, the dummy trench portion 30 is covered by the first interlayer dielectric portion 381 in the front surface 21. By providing the first interlayer dielectric portion 381, the amount of a dopant that is implanted when the first plug region 83 is formed can be adjusted.

FIG. 2E shows an example of the d-d′ cross-section in FIG. 2A. The d-d′ cross-section is a Y-Z cross-section passing through the first interlayer dielectric portion 381, the second interlayer dielectric portion 382, the second contact portion 254 and the dummy trench portion 30.

As shown in FIG. 2E, above the dummy trench portion 30, the front surface side electrode 52 and the dummy conductive portion 34 are connected on a region in which the first interlayer dielectric portion 381 and the second interlayer dielectric portion 382 are not provided. Even if the dummy conductive portion 34 is connected to the front surface side electrode 52, it does not affect the value of the forward-direction voltage Vf of the diode portion 80, hence such design can make the characteristic of the semiconductor device 100 to be adjusted without additional cost for manufacturing.

The second contact portion 254 is provided between the first interlayer dielectric portion 381 and the second interlayer dielectric portion 382 in the trench extending direction of the plurality of trench portions. That is, the second contact portion 254 is provided in a contact hole formed on the interlayer dielectric film 38 in the trench array direction of the plurality of trench portions.

The barrier metal layer 61 formed of titanium, titanium compound or the like may be included inside the second contact portion 254, similar to the first contact portion 154. In addition, a plug layer 62 formed of tungsten and the like may be provided inside the barrier metal layer 61. The semiconductor substrate 10 is connected to the front surface side electrode 52 via the second contact portion 254. Note that the barrier metal layer 61 may be provided on the upper surface of the first interlayer dielectric portion 381 and the second interlayer dielectric portion 382.

The first interlayer dielectric portion 381 may be provided to be sandwiched between two second contact portions 254 in the trench extending direction of the plurality of trench portions. The second interlayer dielectric portion 382 may be provided to be sandwiched between two second contact portions 254 in the trench extending direction of the plurality of trench portions. In this manner, by arranging the first interlayer dielectric portion 381 and the second interlayer dielectric portion 382 to have an island-like shape, an area of the front surface side electrode 52 can be reduced, and the film peeling of the front surface side electrode 52 can be suppressed.

FIG. 2F shows an example of the e-e′ cross-section in FIG. 2A. The e-e′ cross-section is a Y-Z cross-section passing through the first contact portion 154, the anode region 19, and the first plug region 83.

The first contact portion 154 is provided to be extended in the trench extending direction of the plurality of trench portions, and is connected to the semiconductor substrate 10. The first contact portion 154 is connected to the anode region 19 and the first plug region 83. A part of the hole implanted from the first plug region 83 is extracted from the first contact portion 154 via the anode region 19, and therefore a forward voltage of the diode portion 80 is improved, and the reverse recovery loss Err can be reduced.

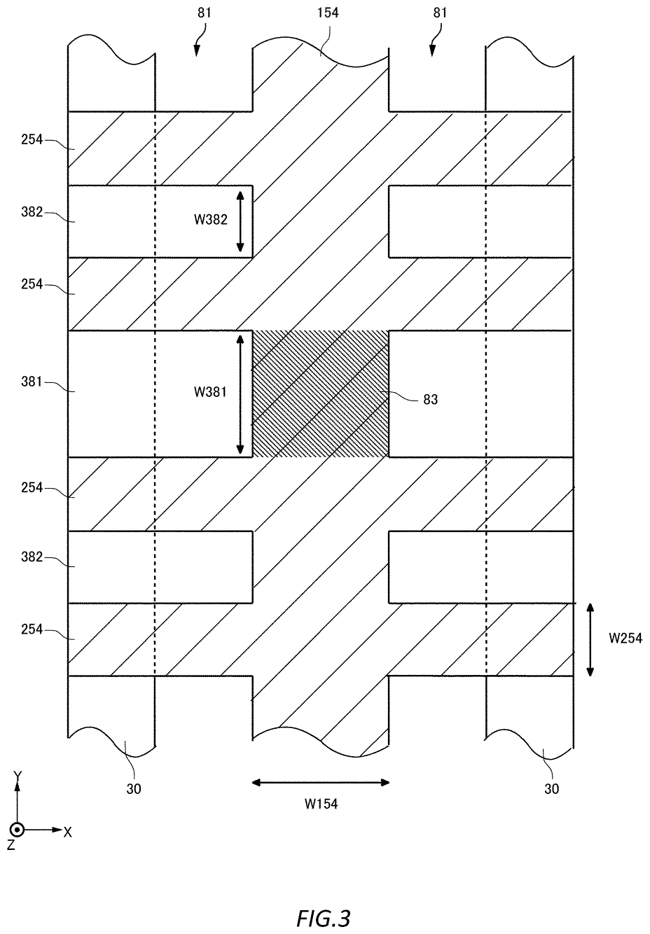

FIG. 3 shows an example of the enlarged drawing of the upper surface of the semiconductor device 100 in the present example. In FIG. 3, the enlarged drawing of one mesa portion 81 provided between two dummy trench portions 30 is shown. In FIG. 3, the first contact portion 154 and the second contact portion 254 are shown by hatching from the upper right to the lower left, and the position of the first plug region 83 that is provided below those contact portions is shown by hatching from the upper left to the lower right.

The hatched portions may have a barrier metal layer 61 (not shown) formed of titanium, titanium compound or the like. In addition, a plug layer 62 (not shown) formed of tungsten and the like may be provided inside the barrier metal layer 61. Furthermore, the barrier metal layer 61 may be provided (not shown) on the upper surface of the interlayer dielectric film 38 (the first interlayer dielectric portion 381 and the second interlayer dielectric portion 382).

The first contact portion 154 has a predetermined width W154 in the trench array direction of the plurality of trench portions. The width W154 of the first contact portion 154 in the trench array direction may be greater than a width W254 of the second contact portion 254 in the trench extending direction. In an example, the W154 may be 0.1 μm or more, or may be 1.0 μm or less.

The second contact portion 254 has a predetermined width W254 in the trench extending direction of the plurality of trench portions. The width W254 of the second contact portion 254 in the trench extending direction may be smaller than the width W154 of the first contact portion 154 in the trench array direction. In an example, the W254 may be 0.1 μm or more, or may be 1.0 μm or less.

The first interlayer dielectric portion 381 has a predetermined width W381 in the trench extending direction of the plurality of trench portions. The width W381 of the first interlayer dielectric portion 381 in the trench extending direction is greater than the width W382 of the second interlayer dielectric portion 382 in the trench extending direction. In this way, the amount of the dopant in the diode portion 80 can be increased, and the breakdown voltage of the semiconductor device 100 can be improved. In an example, the W381 may be 0.1 μm or more, or may be 1.0 μm or less.

The second interlayer dielectric portion 382 has a predetermined width W382 in the trench extending direction of the plurality of trench portions. The width W382 of the second interlayer dielectric portion 382 in the trench extending direction is smaller than the width W381 of the first interlayer dielectric portion 381 in the trench extending direction. In an example, the W382 may be 0 μm or more, or may be 0.8 μm or less.

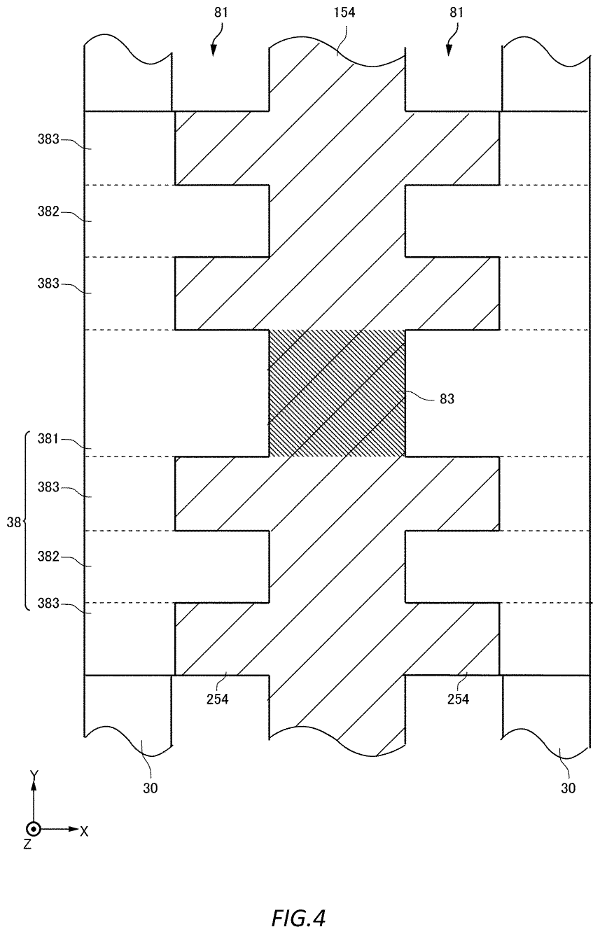

FIG. 4 shows a modification example of the enlarged drawing of the upper surface of the semiconductor device 100 in the present example. The difference from FIG. 3 will be described by using FIG. 4.

The interlayer dielectric film 38 includes a third interlayer dielectric portion 383 provided above the dummy trench portion 30. The third interlayer dielectric portion 383 may be provided between the first interlayer dielectric portion 381 and the second interlayer dielectric portion 382 in the trench extending direction of the plurality of trench portions. The third interlayer dielectric portion 383 may be extended, from above the dummy trench portion 30, in the trench array direction of the plurality of trench portions, and provided above the anode region 19.

A material of the third interlayer dielectric portion 383 may be the same material of that of the first interlayer dielectric portion 381 and the second interlayer dielectric portion 382, or may be a different material. When all of the materials of the first interlayer dielectric portion 381, the second interlayer dielectric portion 382, and the third interlayer dielectric portion 383 are the same, the three interlayer dielectric portions may not be distinguished from one another.

That is, the interlayer dielectric film 38 may be extended in the trench extending direction of the plurality of trench portions and provided to cover the upper surface of the dummy trench portion 30. In addition, the interlayer dielectric film 38 may be extended in the trench array direction of the plurality of trench portions from above the dummy trench portion 30 at a predetermined interval W254 so as to have a predetermined width W381 and W382. In this case, the interlayer dielectric film 38 may be formed to have a comb-teeth shape.

The hatched portions may have a barrier metal layer 61 (not shown) formed of titanium, titanium compound or the like. In addition, a plug layer 62 (not shown) formed of tungsten and the like may be provided inside the barrier metal layer 61. Furthermore, the barrier metal layer 61 may be provided (not shown) on the upper surface of the interlayer dielectric film 38 (the first interlayer dielectric portion 381, the second interlayer dielectric portion 382, and third interlayer dielectric portion 383).

The second contact portion 254 is provided to be extended in the trench array direction of the plurality of trench portions from the end portion of one third interlayer dielectric portion 383 to the end portion of another third interlayer dielectric portion 383 in a top view, and connected to the mesa portion 81. In this way, the hole that is implanted from the first plug region 83 can be extracted from the second contact portion 254 via the anode region 19, and the forward-direction voltage Vf of the diode portion 80 can be improved.

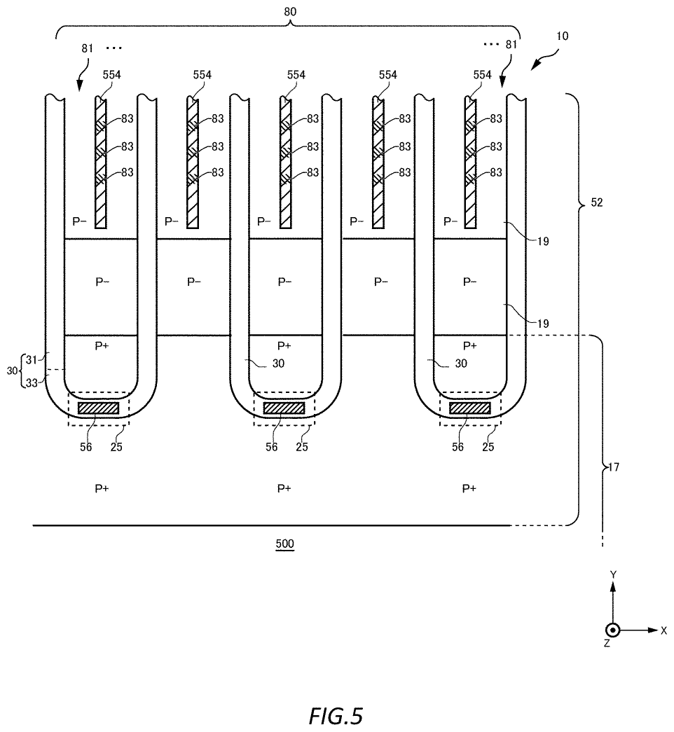

FIG. 5 shows an example of the upper surface of the semiconductor device 500 in a comparative example. The difference from FIG. 2A showing an example of the upper surface of the semiconductor device 100 in the present example will be described by using FIG. 5.

In the semiconductor device 500 in the comparative example, the second contact portion 254 is not provided, but only a contact portion 554 is provided. The contact portion 554 may have the same configuration similar to that of the first contact portion 154 in the semiconductor device 100 in the present example. That is, the contact portion 554 may be provided inside the contact hole formed on the interlayer dielectric film.

Since the second contact portion 254 is not provided in the semiconductor device 500 in the comparative example, the amount of holes extracted from the front surface side electrode 52 is fewer, compared to the semiconductor device 100 in the present example. Accordingly, the semiconductor device 500 in the comparative example has less forward-direction voltage Vf and greater reverse recovery loss Err than the semiconductor device 100 in the present example.

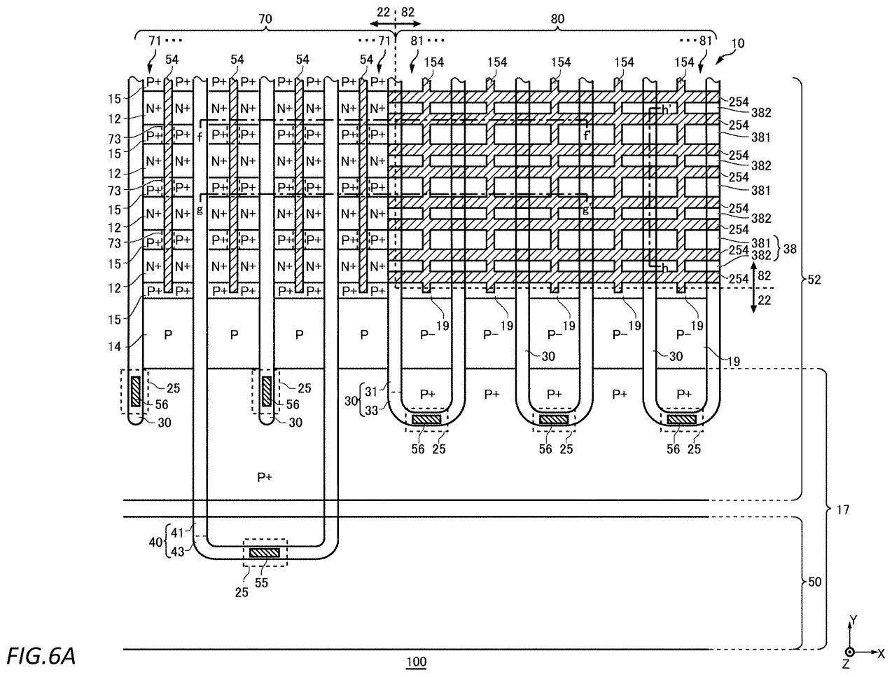

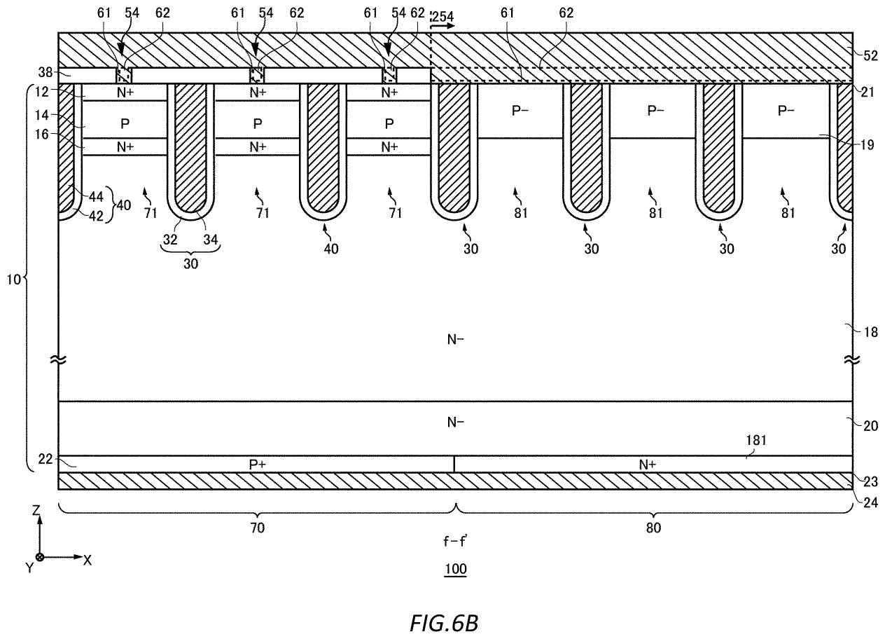

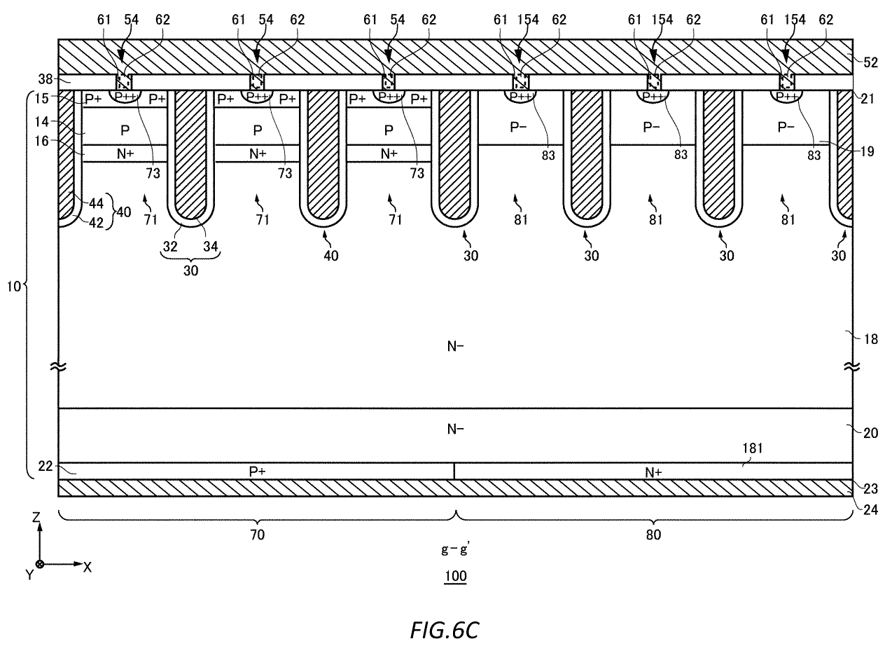

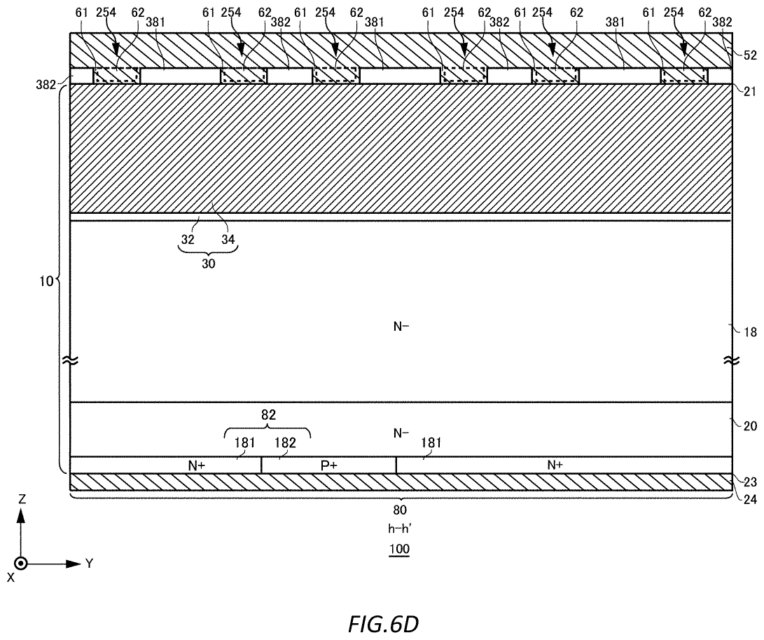

FIG. 6A shows a modification example of the upper surface of the semiconductor device 100 in the present example. The semiconductor device 100 may be a semiconductor chip further including a transistor portion 70. For example, the semiconductor device 100 is a reverse conducting IGBT (RC-IGBT). The transistor portion 70 may include a boundary region in a portion adjacent to the diode portion 80. The transistor portion 70 in the present example does not include the boundary region.

The transistor portion 70 is a region obtained by projecting a collector region 22 provided in a back surface side of a semiconductor substrate 10 onto an upper surface of the semiconductor substrate 10. The collector region 22 has the second conductivity type. The collector region 22 in the present example is of the P+ type as an example. The transistor portion 70 includes a transistor such as an IGBT.

The semiconductor device 100 in the present example includes the gate trench portion 40, the dummy trench portion 30, an emitter region 12, a base region 14, a contact region 15, the well region 17, and the anode region 19 on the front surface 21 of the semiconductor substrate 10. The semiconductor device 100 in the present example includes a second plug region 73 provided in the mesa portion 71 of the transistor portion 70 and a first plug region 83 provided in the mesa portion 81 of the diode portion 80. In addition, the semiconductor device 100 in the present example includes the front surface side electrode 52 and a gate metal layer 50 provided above the front surface 21 of the semiconductor substrate 10.

The interlayer dielectric film 38 in the present example includes a first interlayer dielectric portion 381 and a second interlayer dielectric portion 382. The first interlayer dielectric portion 381 and the second interlayer dielectric portion 382 may be formed of the same material, or may be formed of different materials.

The second interlayer dielectric portion 382 is provided, in the trench array direction, to be sandwiched between a plurality of first contact portions 154 being extended in the trench extending direction. The second interlayer dielectric portion 382 is provided, in the trench extending direction, to be sandwiched between the plurality of second contact portions 254 extending in the trench array direction. That is, the second interlayer dielectric portion 382 is provided to have an island-like shape above the upper surface of the semiconductor substrate 10. In this way, an area of the plug layer 62 of the front surface side electrode 52 is reduced, suppressing the film peeling of the plug layer 62.

The gate metal layer 50 is formed of a material including metal. At least a partial region of the gate metal layer 50 may be formed of metal such as aluminum (Al), or an alloy including aluminum, for example, a metal alloy such as aluminum-silicon alloy (Al—Si), aluminum-silicon-copper alloy (Al—Si—Cu). The gate metal layer 50 is provided to be separated from the front surface side electrode 52.

The front surface side electrode 52 and the gate metal layer 50 are provided above the semiconductor substrate 10 to sandwich the interlayer dielectric film 38. The interlayer dielectric film 38 is omitted in FIG. 6A. A contact hole 55 is provided to pass through the interlayer dielectric film 38.

The contact holes 55 connect the gate metal layer 50 and the gate conductive portions inside the transistor portions 70. In the contact hole 55, a plug formed of tungsten or the like may be formed via the barrier metal.

In the modification example shown in FIG. 6A, the contact portion 54 is provided in the transistor portion 70. The contact portion 54 is formed on the upper surface of each region of the emitter region 12 and the contact region 15. The width of the contact portion 54 in the trench array direction of the plurality of trench portions may be the same as the width of the first contact portion 154 in the trench array direction, and may have the same configuration as that of the first contact portion 154. The width of the contact portion 54 of the trench array direction may be different from the width of the first contact portion 154 in the trench array direction.

The gate trench portion 40 is put into an array at a predetermined interval along a predetermined array direction (the X axis direction in the present example). The gate trench portion 40 in the present example may include: two extending portions 41 which extend along an extending direction (the Y axis direction in the present example) parallel to the front surface 21 of the semiconductor substrate 10 and perpendicular to the array direction; and a connecting portion 43 which connects the two extending portions 41.

At least a part of the connecting portion 43 may be formed to have a curved shape. By connecting end portions of the two extending portions 41 of the gate trench portion 40, the electric field strength at the end portions of the extending portions 41 can be reduced. The gate metal layer 50 may be connected to the gate conductive portion at the connecting portion 43 of the gate trench portion 40.

The transistor portion 70 in the present example has structure in which one gate trench portion 40 and one dummy trench portion 30 are arrayed alternatively and repeatedly. That is, the transistor portion 70 in the present example has the gate trench portions 40 and the dummy trench portions 30 at a ratio of 1:1. For example, the transistor portion 70 has one extending portion 31 between two extending portions 41. In addition, the transistor portion 70 has one extending portion 41 between two extending portions 31.

It is noted however that the ratio of the gate trench portions 40 and the dummy trench portions 30 is not limited to the present example. The ratio of the gate trench portions 40 and the dummy trench portions 30 may be 2:3 or may be 2:4. Alternatively, with all trench portions being the gate trench portions 40, the transistor portion 70 does not need to include the dummy trench portion 30.

A mesa portion 71 is a mesa portion provided to be in direct contact with the trench portion in a plane parallel to the front surface 21 of the semiconductor substrate 10. The mesa portion 71 is provided to be in direct contact with at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter region 12 and the contact region 15 are alternately provided in the extending direction (the Y axis direction in the present example) of the trench portion on the front surface 21 of the semiconductor substrate 10.

The base region 14 is a region of the second conductivity type provided above the drift region 18. The doping concentration of the base region 14 may be higher than the doping concentration of the anode region 19. That is, in the present example, the doping concentration of the anode region 19 is lower than the doping concentration of the base region 14. The base region 14 is of the P type by way of example. The base region 14 may be provided at both end portions of the mesa portion 71 in the Y axis direction, at the front surface 21 of the semiconductor substrate 10. In FIG. 6A, only one end portion of the base region 14 in the Y axis direction is shown.

The emitter region 12 is a region of the first conductivity type which is provided above the base region 14 and has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71.

In addition, the emitter region 12 may or may not be in contact with the dummy trench portion 30. The emitter region 12 in the present example is in contact with the dummy trench portion 30.

The contact region 15 is a region of the second conductivity type having a doping concentration higher than that of the base region 14. The contact region 15 in the present example is of the P+ type as an example. The contact region 15 in the present example is provided at the front surface 21 of the mesa portion 71. The contact region 15 may be provided in the X axis direction from one to another of the two trench portions sandwiching the mesa portion 71. The contact region 15 may or may not be in contact with the gate trench portion 40 or the dummy trench portion 30. The contact region 15 in the present example is in contact with the dummy trench portion 30 and the gate trench portion 40.

The doping concentration of the contact region 15 is lower than the doping concentration of the first plug region 83 provided in the diode portion 80. That is, the doping concentration of the first plug region 83 is higher than the doping concentration of the contact region 15. The doping concentration of the contact region 15 may be 2E19 cm⁻³ or more, or may be 2E20 cm⁻³ or less.

The second plug region 73 is a region of the second conductivity type having a doping concentration higher than that of the base region 14. The second plug region 73 in the present example is a P++ type, as an example. The doping concentration of the second plug region 73 may be the same as or may be different from the doping concentration of the first plug region 83. The second plug region 73 may be formed by implanting a dopant via the contact hole for providing the contact portion 54.

The second plug region 73 is provided in the contact region 15, and may not be provided in the emitter region 12. The second plug region 73 in the present example is provided at the same position as that of the first plug region 83 in the trench array direction of the plurality of trench portions. In this way, the first plug region 83 and the second plug region 73 can be formed by using the same ion implantation process and the manufacturing cost can be reduced.

FIG. 6B shows an example of the f-f′ cross-section in FIG. 6A. The f-f′ cross-section is an X-Z cross-section passing through the second contact portion 254. The semiconductor device 100 in the present example has, in the f-f′ cross-section, the emitter region 12, the base region 14, an accumulation region 16, the drift region 18, the buffer region 20, the semiconductor substrate 10 on which the first plug region 83 and the second plug region 73 are provided, the interlayer dielectric film 38, the front surface side electrode 52, and the back-surface-side electrode 24. In addition, the cathode region 82 in the present example may include a first cathode portion 181 and a second cathode portion 182 in the trench extending direction (the Y axis direction). The first cathode portion 181 and the second cathode portion 182 will be described below.

The accumulation region 16 is a region of the first conductivity type provided below the base region 14 in the depth direction of the semiconductor substrate 10, which has a doping concentration higher than that of the drift region 18. The accumulation region 16 in the present example is of the N+ type as an example. The accumulation region 16 is provided in the transistor portion 70, but not provided in the diode portion 80. By providing the first accumulation region 16, the carrier injection enhancement effect (IE effect) can be increased, and the ON voltage of the transistor portion 70 can be reduced.

One or more gate trench portions 40 are provided on the front surface 21. Each trench portion is provided from the front surface 21 to the drift region 18. In a region where at least one of the emitter region 12, the base region 14 or the accumulation region 16 is provided, each trench portion passes through the region to reach the drift region 18. The configuration of the trench portion passing through the doping region is not limited to the one manufactured in the order of forming the doping region and then forming the trench portion. The configuration of the trench portion passing through the doping region also includes a configuration of the doping region being formed between the trench portions after forming the trench portions.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on the side of the mesa portion 71 by sandwiching the gate dielectric film 42 in a depth direction of the semiconductor substrate 10. When a predetermined voltage is applied to the gate conductive portion 44, a channel is formed by an electron inversion layer in a surface layer of the base region 14 at a boundary in contact with the gate trench.

FIG. 6C shows an example of the g-g′ cross-section of FIG. 6A. The g-g′ cross-section is an X-Z cross-section passing through the first plug region 83 and the second plug region 73. The difference from FIG. 6B will be described by using FIG. 6C.

In the g-g′ cross-section shown in FIG. 6C, the contact region 15 and the second plug region 73 are provided in the transistor portion 70. The position of the lower end of the second plug region 73 in the depth direction of the semiconductor substrate 10 may be deeper than the position of the lower end of the contact region 15. In this way, the hole can be more easily extracted via the second plug region 73, and the latch-up resistance of the semiconductor device 100 can be improved.

FIG. 6D shows an example of the h-h′ cross-section in FIG. 6A. The h-h′ cross-section is a Y-Z cross-section passing through the first interlayer dielectric portion 381, the second interlayer dielectric portion 382, the second contact portion 254 and the dummy trench portion 30. The cathode region 82 may have the first cathode portion 181 and the second cathode portion 182. The first cathode portion 181 is a region of the first conductivity type having a doping concentration higher than that of the drift region 18. In an example, the first cathode portion 181 is of the N+ type.

The second cathode portion 182 is a region of the second conductivity type provided to be in direct contact with the first cathode portion 181 on the back surface 23 of the semiconductor substrate 10. That is, the second cathode portion 182 may be in direct contact with the first cathode portion 181. In an example, the second cathode portion 182 is of the P+ type. The first cathode portion 181 and the second cathode portion 182 may be alternately arranged in the trench extending direction (the Y axis direction). In addition, the width of each of the first cathode portion 181 and the second cathode portion 182 in the trench extending direction (the Y axis direction) can be freely set without any limitation on the structure at the front surface 21 side of the semiconductor substrate 10.

The first cathode portion 181 may be formed by ion implantation of an N type dopant, after ion implantation of a P type dopant by an ion implantation process for forming the second cathode portion 182.

On the contrary, the second cathode portion 182 may be formed by ion implantation of a P type dopant after ion implantation of an N type dopant by an ion implantation process for forming the first cathode portion 181.

The first cathode portion 181 and the second cathode portion 182 may be alternately arranged in any direction. The first cathode portions 181 and the second cathode portion 182 in the present example are alternately arrayed in the trench extending direction (for example, the Y axis direction), but may be alternately arrayed in the trench array direction (for example, the X axis direction). The first cathode portion 181 and the second cathode portion 182 may be arranged in the striped shapes in a top view. One of the first cathode portion 181 and the second cathode portion 182 may be formed in the dot shape.

In the cathode region 82 in the diode portion 80 in the present example, the second cathode portion 182 may be provided. In the cathode region 82 in the diode portion 80 in the present example, the first cathode portion 181 and the second cathode portion 182 may be alternately provided. In the cathode region 82 in the diode portion 80 in the present example the first cathode portion 181 and the second cathode portion 182 may be provided to contact each other. In this way, the concentration of the dopant of the first conductivity type in the cathode region 82 decreases, and the forward-direction voltage Vf of the diode portion 80 can be improved.

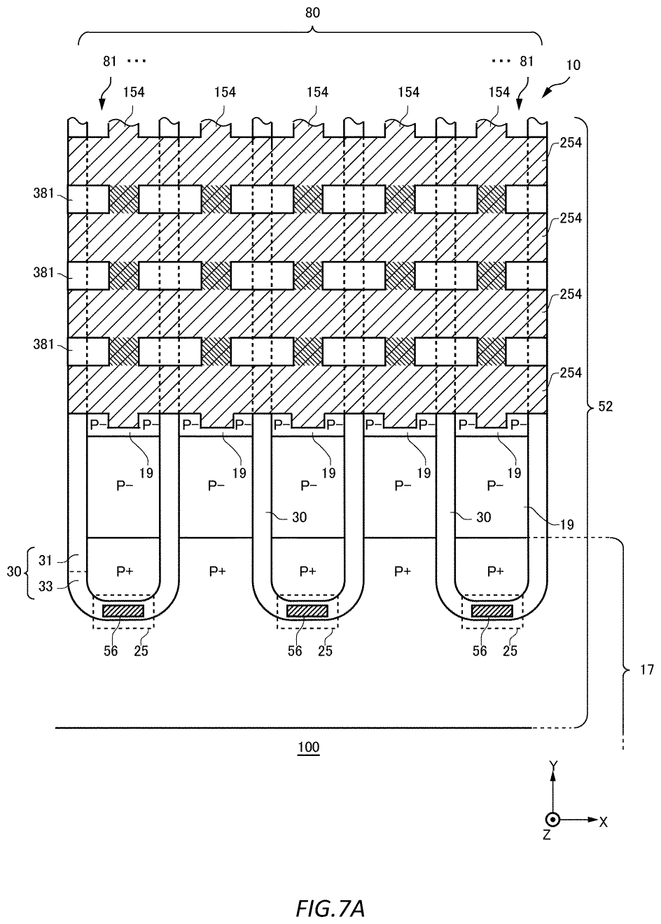

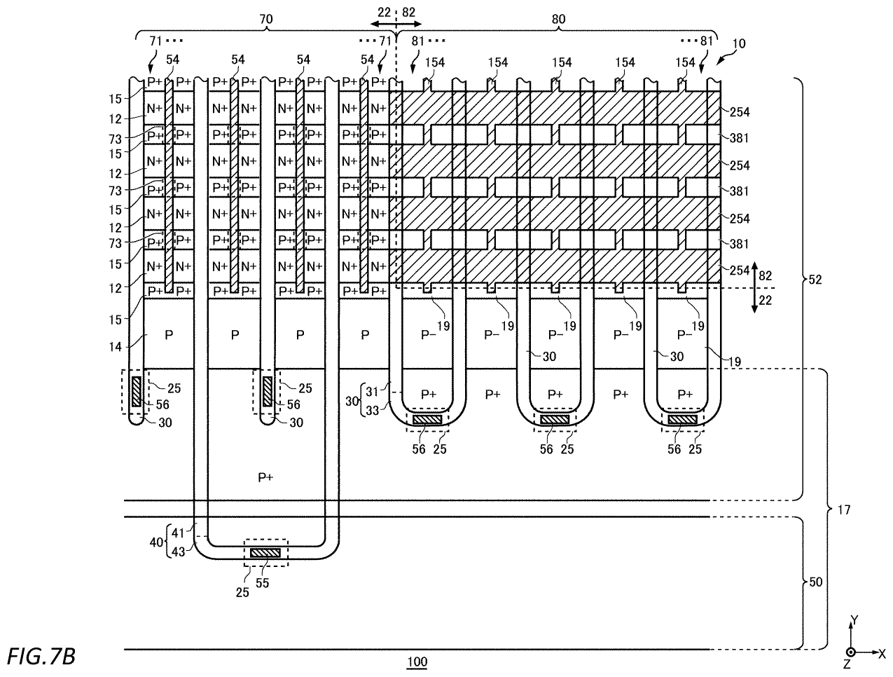

FIG. 7A shows a modification example of the upper surface of the semiconductor device 100 in the present example. The difference from FIG. 2A will be described by using FIG. 7A.

In the modification example shown in FIG. 7A, the second interlayer dielectric portion 382 is not provided. In the present example, in a region between two first interlayer dielectric portions 381 adjacent to each other in the trench extending direction, the second interlayer dielectric portion 382 is not provided, but the second contact portion 254 is provided. In this way, a similar effect as that of FIG. 2A can be obtained and the extractions of the hole from the anode region 19 can be increased, such that the forward-direction voltage Vf of the diode portion can be improved.

FIG. 7B shows a modification example of the upper surface of the semiconductor device 100 in the present example. The semiconductor device 100 may be a semiconductor chip further including a transistor portion 70. For example, the semiconductor device 100 is a reverse conducting IGBT (RC-IGBT). The transistor portion 70 may include a boundary region in a portion adjacent to the diode portion 80. The transistor portion 70 in the present example does not include the boundary region. The difference from FIG. 6A will be described by using FIG. 7B.

In the modification example shown in FIG. 7B, the second interlayer dielectric portion 382 is not provided. In the present example, in a region between two first interlayer dielectric portions 381 adjacent to each other in the trench extending direction, the second interlayer dielectric portion 382 is not provided, but the second contact portion 254 is provided. In this way, a similar effect as that of FIG. 6A can be obtained and the extraction of the hole from the anode region 19 can be increased, such that the forward-direction voltage Vf of the diode portion can be improved.

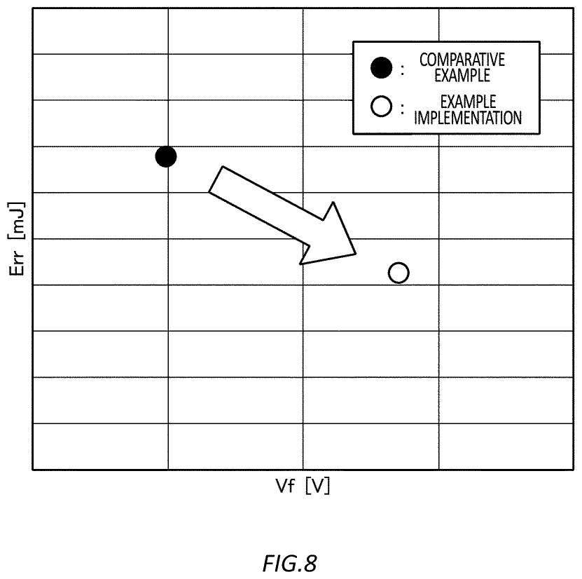

FIG. 8 is a graph indicating a relationship between the forward-direction voltage Vf and the reverse recovery loss Err of the diode portion 80 of the semiconductor device 500 in the comparative example and the semiconductor device 100 in the present example. In FIG. 8, the forward-direction voltage Vf is plotted on the horizontal axis, and the reverse recovery loss Err of the diode portion 80 is plotted on the vertical axis. In the figure, the black circle indicates the semiconductor device 500 in the comparative example, and the white circle indicates the semiconductor device 100 in the embodiment.

In the semiconductor device 100 in the present example, the second contact portion 254 is provided such that the hole current flowing via the front surface side electrode 52 is greater than that of the semiconductor device 500 in the comparative example. In this way, the forward-direction voltage Vf of the semiconductor device 100 can be higher than the forward-direction voltage Vf of the semiconductor device 500 in the comparative example. In addition, the increase of the forward-direction voltage Vf can allow the reverse recovery loss Err of the semiconductor device 100 to be lower than the reverse recovery loss Err of the semiconductor device 500 in the comparative example.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such alterations or improvements are made can be included in the technical scope of the present invention.

It should be noted that the operations, procedures, steps, stages, and the like of each process performed by an apparatus, system, program, and method shown in the claims, embodiments, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10 semiconductor substrate
12 emitter region
14 base region
15 contact region
16 accumulation region
17 well region
18 drift region
19 anode region
20 buffer region
21 front surface
22 collector region
23 back surface
24 back-surface-side electrode
25 connecting portion
30 dummy trench portion
31 extending portion
32 dummy dielectric film
33 connecting portion
34 dummy conductive portion
38 interlayer dielectric film
40 gate trench portion
41 extending portion
42 gate dielectric film
43 connecting portion
44 gate conductive portion
50 gate metal layer
52 front surface side electrode
54 contact portion
55 contact hole
56 contact hole
61 barrier metal layer
62 plug layer
70 transistor portion
71 mesa portion
73 second plug region
80 diode portion
81 mesa portion
82 cathode region
83 first plug region
100 semiconductor device
154 first contact portion
254 second contact portion
181 first cathode portion
182 second cathode portion
381 first interlayer dielectric portion
382 second interlayer dielectric portion
383 third interlayer dielectric portion
500 semiconductor device
554 contact portion.

What is claimed is:

1. A semiconductor device comprising a diode portion, comprising:
a plurality of trench portions provided at a front surface of a semiconductor substrate;
a drift region of a first conductivity type provided on the semiconductor substrate;
an anode region of a second conductivity type provided above the drift region in the diode portion;
a first plug region of the second conductivity type which is provided above the drift region in the diode portion and has a doping concentration higher than a doping concentration of the anode region;
a front surface side electrode provided above the semiconductor substrate; and
an interlayer dielectric film provided above a mesa portion provided between the plurality of trench portions; wherein
the anode region is connected to the front surface side electrode on side surfaces of the plurality of trench portions.

2. The semiconductor device according to claim 1, comprising
above the mesa portion, a first contact portion being extended in a trench extending direction of the plurality of trench portions and connected to the anode region and the first plug region.

3. The semiconductor device according to claim 2, comprising a second contact portion that is extended, on the front surface of the semiconductor substrate, from one side wall of a trench portion among the plurality of trench portions to another side wall of a trench portion in a trench array direction of the plurality of trench portions, and connected to the mesa portion.

4. The semiconductor device according to claim 3, wherein
the second contact portion is extended, in the trench array direction of the plurality of trench portions, beyond at least one trench portion of the plurality of trench portions, and connected to the at least one trench portion.

5. The semiconductor device according to claim 4, wherein
a width of the first contact portion in the trench array direction is greater than a width of the second contact portion in the trench extending direction.

6. The semiconductor device according to claim 4, wherein
the second contact portion is provided above the anode region and the plurality of trench portions alternately provided in the trench array direction.

7. The semiconductor device according to claim 4, wherein
a plurality of the second contact portions are provided above the anode region and the plurality of trench portions alternately provided in the trench array direction.

8. The semiconductor device according to claim 4, wherein
the interlayer dielectric film has a first interlayer dielectric portion provided between the first plug region and the plurality of trench portions in the trench array direction, in a top view.

9. The semiconductor device according to claim 8, wherein
the interlayer dielectric film has a second interlayer dielectric portion provided between the anode region and the plurality of trench portions in the trench array direction, in a top view.

10. The semiconductor device according to claim 9, wherein
a width of the first interlayer dielectric portion in the trench extending direction is greater than a width of the second interlayer dielectric portion in the trench extending direction.

11. The semiconductor device according to claim 8, wherein
the first interlayer dielectric portion is sandwiched, in the trench array direction, between a plurality of the first contact portions being extended in the trench extending direction; and
the first interlayer dielectric portion is sandwiched, in the trench extending direction, between a plurality of the second contact portions being extended in the trench array direction.

12. The semiconductor device according to claim 9, wherein
the second interlayer dielectric portion is sandwiched, in the trench array direction, between a plurality of the first contact portions being extended in the trench extending direction; and
the second interlayer dielectric portion is sandwiched, in the trench extending direction, between a plurality of the second contact portions being extended in the trench array direction.

13. The semiconductor device according to claim 4, wherein
the front surface side electrode has a barrier metal layer provided inside the first contact portion and the second contact portion.

14. The semiconductor device according to claim 1, comprising a transistor portion having a base region of the second conductivity type provided above the drift region, wherein
a doping concentration of the anode region is lower than a doping concentration of the base region.

15. The semiconductor device according to claim 14, comprising a contact region of the second conductivity type provided above the drift region in the transistor portion, wherein
the doping concentration of the first plug region is higher than a doping concentration of the contact region.

16. The semiconductor device according to claim 14, comprising a second plug region of the second conductivity type which is provided above the drift region in the transistor portion and has a doping concentration higher than a doping concentration of the base region.

17. The semiconductor device according to claim 1, wherein the doping concentration of the anode region is 4E16 cm⁻³ or more or 1E17 cm⁻³ or less.

18. The semiconductor device according to claim 1, wherein the doping concentration of the first plug region is 2E19 cm⁻³ or more or 2E20 cm⁻³ or less.

19. The semiconductor device according to claim 1, wherein
the first plug region is provided to be spaced apart from a trench sidewall of the plurality of trench portions in a trench array direction of the plurality of trench portions;
the anode region is provided to be extended from one trench sidewall of the plurality of trench portions to another trench sidewall in the trench array direction; and
the first plug region and the anode region are alternately provided in a trench extending direction of the plurality of trench portions in the mesa portion.

20. The semiconductor device according to claim 1, wherein in the mesa portion, an area of the anode region on the front surface of the semiconductor substrate is greater than an area of the first plug region on the front surface of the semiconductor substrate.

21. The semiconductor device according to claim 1, wherein
The front surface side electrode has a plug layer composed of tungsten.

22. The semiconductor device according to claim 1, comprising a cathode region of the first conductivity type provided on a back surface of the semiconductor substrate in the diode portion; wherein
a doping concentration of the cathode region is 5E19 cm⁻³ or more or 2E20 cm⁻³ or less.
